(19) United States
(12) Patent Application Publication
(10) Pub. No.: US 2004/0251498 A1
(43) Pub. Date: Dec. 16, 2004

(54) Lateral islolated gate bipolar transistor device

(76) Inventors: Rene Paul Zingg, Nijmegen (NL); Johannes Van Zwol, Nijmegen (NL); Arnoldus Johannes Maria Emmerik, Nijmegen (NL)

Correspondence Address: Philips Electronics North America Corporation, Intellectual Property & Standards, 1109 McKay Drive, M/S41-SJ, San Jose, CA, 95131, US

(21) Appl. No.: 10/494,536

(22) PCT Filed: Oct. 22, 2002
(86) PCT No.: PCT/IB02/04425

(30) Foreign Application Priority Data
Nov. 1, 2001 (EP) 01204204.0

(51) Int. Cl. H01L 29/76

(52) U.S. Cl. 257/343

(57) ABSTRACT

A lateral isolated gate bipolar transistor (LIGBT) device comprises a substrate (20) and a buried oxide layer (22) on the substrate; a silicon layer (24) on the buried oxide layer, the silicon layer having a laterally extending drift region (26); an emitter/cathode (28) on top of the silicon layer, a collector/anode (30) on top of the silicon layer and laterally separated from the emitter/cathode (28); a dielectric layer (42), e.g. thermally grown oxide, in between the emitter/cathode (28) and the collector/anode (30); a gate electrode (34) on top of the silicon layer (24); and a field plate (38, 40) extending on top or within the field oxide layer to almost an end thereof adjacent to the collector/anode. The region of the silicon layer (24) between an end (46) of the field plate adjacent to the collector/anode (30) and below the level of the field plate (38, 40) and the collector/anode (30) has a Gummel number sufficient to suppress a parasitic bipolar effect at the collector/anode (30) of the LIGBT.

The invention relates to a lateral isolated gate bipolar transistor device.

A lateral isolated gate bipolar transistor device typically comprises a substrate, a buried oxide layer on the substrate, and a silicon layer on the buried oxide layer. The silicon layer contains a laterally extending drift region, an emitter/cathode and a body on one side of this drift region, and a collector/anode on the other. A dielectric layer separates a gate electrode from the channel and the drift region silicon layer. This gate electrode serves also as field-plate on top of the field-oxide, and may be extended by one or several dielectric isolated metal field plates extending across the field- and drift-oxide layer to almost an end thereof adjacent to the collector/anode. These field plates can be electrically connected to the gate, the emitter/cathode, or any other suitable potential in the circuit. Although a LIGBT has the potential of significantly higher saturation currents than LDMOS due to conductivity modulation, a LIGBT with such field-plates in SOI is limited in its attainable breakdown voltage. Although conductivity modulation has been demonstrated with about a three-fold saturation current, the breakdown voltage was significantly lower than in corresponding LDMOS.

The U.S. Pat. No. 5,559,348 discloses a device, the gate region of which has an extension reaching partly across the field oxide layer. This extension of the gate does not form a field plate to maximize drift doping density as it does not reach across the complete field oxide layer. Therefore, in this LIGBT, the parasitic bipolar transistor which might be formed between the emitter/cathode layer, the base layer and the area of the silicon layer next to the collector/anode has a very wide base width and a very low gain. Since the effective gain of this device can not become large or infinite, BVceo of the parasitic transistor will also not limit the break down voltage of this LIGBT. Generally speaking, it would also be desirable to have the field plate extending across the entire field oxide layer in order to make a higher drift doping possible by the influence of such a field plate.

From IEEE ED45, pages 2251 to 2254 “Lateral IGBT in thin SOI for high voltage, high speed power IC”, Ying-Keung Leung et al, a high voltage LIGBT is known which is built in ultra-thin silicon on insulator technology with a linearly graded doping profile. The graded doping profile is supposed to improve the break down voltage to 720 V measured in a LIGBT built in 0.5 μvm SOI with a 4 μm buried oxide. Although the graded doping profile obviously improves the break down voltage capability, the drift doping can not be maximized because the gate extension of the gate extends only the short distance across the field oxide in this device.

It is the objective of the invention to provide a LIGBT in SOI which has an improved high end capability, in particular a higher breakdown voltage.

For this purpose, a lateral isolated gate bipolar transistor device is provided comprising a substrate; a buried oxide layer on the substrate; a silicon layer on the buried oxide layer, the silicon layer having a laterally extending drift region; a gate electrode above a channel region which gate electrode also serves as field-plate, an emitter/cathode and a body on one side of the drift region; a collector/anode on the other side of the drift region; a dielectric layer which separates a gate electrode from the channel and the drift region silicon layer; the field plate extending to almost an end thereof adjacent to the collector/anode; wherein a region of the silicon layer between an end of the field plate adjacent to the collector/anode and below the level of the field plate and the collector/anode has a Gummel number sufficient to suppress a parasitic bipolar transistor at the collector/anode of the LIGBT.

The Gummel number is defined as the doping density (doping per area) of the base or the integral of the doping concentration over the base width. As a consequence a high Gummel number (large base width and/or high base doping) will produce a low saturation current and a low gain.

The inventors have found that due to “base width” modulation and the corresponding decrease in the Gummel number by potential differences between the field plate or the further field plate and collector/anode, the effective gain of this device can become infinite, limiting the breakdown voltage between emitter/cathode and collector/anode (BVce) of the LIGBT. Therefore, increasing the Gummel number sufficiently to suppress a parasitic bipolar effect at the collector/anode of the LIGBT solves this problem. The invention prevents a parasitic bipolar effect with its risk of base punch-through at the collector/anode or anode of the LIGBT, therefore allowing the device to reach its inherent capabilities as to the breakdown voltage.

According to an advantageous embodiment, the invention provides a LIGBT wherein the field plate extends close to the collector/anode, but with a sufficient distance such that a Gummel number is provided which is able to suppress a parasitic bipolar effect at the collector/anode of the LIGBT. The field plate extends as close to the collector/anode as possible, but with a sufficient distance such that a Gummel number is provided which is able to suppress a parasitic bipolar effect at the collector/anode of the LIGBT. It is an advantage of the embodiment that the Gummel number can efficiently be increased to the desired level just by appropriately designing the spacing between the first field plate portion or the second field plate portion adjacent to the collector/anode at the collector/anode itself.

According to an advantageous embodiment, the invention provides a LIGBT wherein the lateral distance between the end of the field plate portion closest to the collector/anode and the collector/anode is increased by shortening this field plate portion. The invention in such a LIGBT is to have a field plate covering the complete drift region of the LIGBT. However, slightly shortening the field plate adjacent to the collector/anode has no major negative effect on the influence of the field plate to the drift region but, on the other hand, has the desired effect to suppress a parasitic bipolar effect in the region between the field plate and the collector/anode.

According to an advantageous embodiment, the invention provides a LIGBT having a drift region length of 10-80 μm, depending on the desired voltage rating, wherein the field plate portion adjacent to the collector/anode ends 5-18 μm short of the end of the drift region. In a typical LIGBT, the length of the drift region is in the range of 10-80 μm. In such a LIGBT it is sufficient for the desired effect to shorten the first field plate portion or the second field plate portion in this way.

According to an advantageous embodiment, the invention provides a LIGBT wherein the lateral distance between the end of the field plate portion adjacent to the collector/anode and the collector/anode is extended by placing the collector/anode further away from the end of the first field plate portion or the second field plate portion. By removing the collector/anode away from the end of the field plate, the desired effect can also be achieved without effecting the benefits of the field plate. However, it is to be noted, that the invention can also be embodied in advantageous way by taking both measures, i.e. slightly shortening the first field plate portion or the second field plate portion and removing the collector/anode from the end of the field plate.

According to an advantageous embodiment, the invention provides a LIGBT having a drift region length of 10-80 μm, wherein the collector/anode is spaced by 5-18 μm away from the end of the drift region. In a typical LIGBT with a length of the drift region of 10-80 μm, it is sufficient to space the collector/anode away from the drift region in this way. It is apparent that this amount of additional spacing of the collector/anode from the drift region does not substantially influence the foot print of the die of the device on a chip.

According to an advantageous embodiment, the invention provides a LIGBT wherein a high-doped zone is provided below the top of the silicon layer between the field plate portion adjacent to the collector/anode and the collector/anode to provide a Gummel number sufficient to suppress a parasitic bipolar effect at the collector/anode of the LIGBT. Providing such a high-doped zone is a means to achieve the desired effect. The high-doped zone may be provided in addition to any of the above mentioned features in which case the advantageous effects of the features lead to a high degree of suppression of a parasitic bipolar effect at the collector/anode of the LIGBT.

According to an advantageous embodiment, the invention provides a LIGBT wherein the high-doped zone has a doping two or more times as high as the doping in the surrounding silicon layer. Such a high-doped zone is easy to produce during the manufacturing of the LIGBT as it is only two times as higher as the doping in the silicon layer. On the other hand, such a zone with this additional doping has proved to bring about the desired effect.

According to an advantageous embodiment, the invention provides a LIGBT wherein the high-doped zone ends short of the collector/anode. If the high-doped zone does not touch the collector/anode or anode the “emitter efficiency” of the LIGBT anode will not be degraded.

According to an advantageous embodiment, the invention provides a LIGBT wherein the high-doped zone ends at the field oxide layer. Thereby, the effect of the high-doped zone is advantageously placed for maximum effect, while minimizing chip area required for this measure.

According to an advantageous embodiment, the invention provides a LIGBT comprising a collector/anode contact out of metal, wherein the collector/anode contact extends over the collector/anode and drift region junction to prevent depletion in this region.

According to an advantageous embodiment, the invention provides a LIGBT comprising a collector/anode contact out of metal, wherein the collector/anode contact extends at least 2 μm over the collector/anode and drift region junction to prevent depletion in this region.

According to an advantageous embodiment, the invention provides a LIGBT wherein the dielectric layer comprises a thermally grown field oxide and drift oxide in between the emitter/cathode and the collector/anode.

According to an advantageous embodiment, the invention provides a LIGBT wherein the gate electrode is extended by at least one metal field plate which are isolated by a dielectric and extends across the field oxide and drift oxide layer to almost an end thereof adjacent to the collector/anode.

Preferred embodiments of the present invention are now described with reference to the drawings in which:

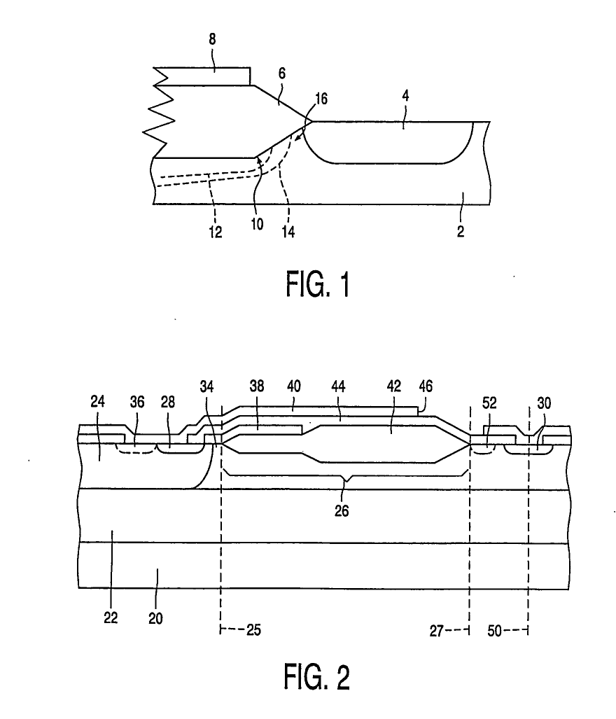

FIG. 1 shows a collector/anode region of LIGBT with an indication of a parasitic bipolar device; and

FIG. 2 shows an embodiment of the LIGBT of the invention.

FIG. 1 shows a collector/anode region of a LIGBT to explain the presence of a parasitic bipolar device in this area and the effect thereof. Next to a buried oxide layer (not shown) in which, for example an n-doped-collector/anode region 4 is provided next to a top oxide layer 6 on top of which a field plate 8 is provided. The collector/anode region 4 or the anode is a “hole (defect-electron)-emitter” in the device. The lines 12 and 14 indicate the limit of the space charge zone 10 at two different field-plate 8 to collector/anode 4 bias conditions. This illustrates the modulation of the neutral base zone 16 between collector/anode junction and space-charge limit and thereby also the Gummel number of this parasitic device. Therefore, the “base width” modulation results in a decrease in the Gummel number by potential differences between the field plate and the collector/anode. Each of the given embodiments serves to increase the Gummel number and thereby the gain of this parasitic device, even at high bias between collector/anode and field-plate.

FIG. 2 shows a LIGBT device which comprises a substrate 20 and a buried oxide layer 22 on the substrate 20 and a silicon layer 24 on the buried oxide layer 22, the silicon layer 24 having a laterally extending drift region 26. An emitter/cathode 28 is located on the left of the channel region 34. A collector/anode 30 is to the right of said drift region 26. A top oxide layer 42 is provided in between the emitter/cathode 28 and the collector/anode 30. A gate is located on top of the gate dielectric and the channel 34 next to the emitter/cathode 28 and may extend as field-plate 38 onto the dielectric 42 (field-oxide). A body region contains source 38 and channel 34 and is contacted 36 to the left of the source, or to reduce second-breakdown effects in an alternating pattern with the source against the polysilicon edge (not shown, as region 36 would be in front and behind the cross-sectional plane depicted in FIG. 2).

The field-plate 38 can be extended or replaced by any available metal layer 40 connected to source 28 or gate or any other suitable circuit potential. This could be motivated by reducing the electric field in the dielectric and thereby the silicon by inserting the additional dielectric 44, which insulates the gate polysilicon from the metal.

The invention is not restricted to this particular field plate arrangement. There could be only one of the two field-plate portions extending across the field oxide layer to almost an end thereof adjacent to the collector/anode. Furthermore, the field plate may extend within a field oxide region. Examples for various field plate arrangements are shown in U.S. Pat. No. 5,246,870, U.S. Pat. No. 5,362,979, WO 99/34449 and WO 00/31776.

As can be seen from FIG. 2, the end 46 of the last field plate portion 40 is further removed from the end of the drift region 26 indicated by line 27 in FIG. 2, as compared to the end of field plate 8 shown in FIG. 1. Therefore, the lateral distance between the end 46 of the field plate portion 40 adjacent to the collector/anode 30 and the collector/anode is extended. In a typical LIGBT having a drift region length of 10-80 μm, the end 46 of the field plate portion 40 is removed by 5 to 18 μm from the line 27 indicating the end of the drift region 26.

As can be seen from a comparison of FIGS. 1 and 2, the collector/anode 30 is further removed in the LIGBT of FIG. 2 from the end of the drift region 26 indicated by line 27 as compared to the collector/anode 4 of FIG. 1. Therefore, the lateral distance between the end 46 of the field plate portion 40 and the collector/anode 30 is further extended as compared to the respective distance in the LIGBT of FIG. 1. In a typical LIGBT having a drift region length of 60-80 μm, the distance between the end of the drift region indicated by line 27 and the collector/anode 30, in particular a center line 50 thereof, is between 5 and 18 μm respectively.

As can be seen from FIG. 2, there is a high-doped zone 52 in between the drift region 26 and the collector/anode 30 next to a top surface of the silicon layer 24. In other words, the high-doped zone 52 is provided below the top of the silicon layer 24 between the end of the field plate portion 40 and the collector/anode 30. The high-doped zone 52 has a doping at least two times as high as the doping of the area of the silicon layer 24 surrounding the high-doped zone 52. The high-doped zone 52 ends short of the collector/anode 30 and also short of the field oxide layer 42 as can be seen from FIG. 2.

To summarize, retracting the collector/anode or the field-plate from the end of the drift region increases the Gummel number by widening the effective base of the parasitic bipolar transistor (not depleted zone next to anode/collector), whereas the interposed high-doped zone increases the Gummel number with additional doping. Therefore, a parasitic bipolar action in the collector/anode region is prevented.

It is to be understood that the above description is intended to be illustrative and not restrictive. Many embodiments will be apparent to those skilled in the art upon reviewing the above description. The scope of the invention should, therefore, be determined not as reference to the above description, but should instead be determined with reference to the appended claims along with the full scope of equivalence to which such claims are entitled.

1. A lateral isolated gate bipolar transistor (LIGBT) device comprising:
a substrate (20);
a buried oxide layer (22) on the substrate;
a silicon layer (24) on the buried oxide layer, the silicon layer having a laterally extending drift region (26);
a gate electrode above a channel region which gate electrode also serves as field-plate;
an emitter/cathode (28) and a body on one side of the drift region (26);
a collector/anode (30) on the other side of the drift region (26); and
a dielectric layer (42) which separates a gate electrode from the channel and the drift region silicon layer;
the field plate (38, 40) extending to almost an end thereof adjacent to the collector/anode; wherein
a region of the silicon layer (24) between an end (46) of the field plate adjacent to the collector/anode (30) and below the level of the field plate (38, 40) and the collector/anode (30) has a Gummel number sufficient to suppress a parasitic bipolar transistor at the collector/anode (30) of the LIGBT.

2. The lateral isolated gate bipolar transistor device of claim 1, wherein the lateral distance between the end of the field plate portion closest to the collector/anode and the collector/anode is increased by shortening the field plate portion.

3. The lateral isolated gate bipolar transistor device of claim 2, wherein the lateral distance between the end of the field plate portion adjacent to the collector/anode (30) and the collector/anode is extended by shortening the field plate portion (38) or the further field plate (40).

4. The lateral isolated gate bipolar transistor device of claim 3 having a drift region length of 10-80 μm, depending on the desired voltage rating, wherein the first field plate portion or the second field plate portion adjacent to the collector/anode ends 5-18 μm short of the end (27) of the drift region (26).

5. The lateral isolated gate bipolar transistor device of claim 3, wherein the lateral distance between the end of the field plate portion adjacent to the collector/anode and the collector/anode (30) is extended by placing the collector/anode (30) further away from the end of the first field plate portion (38) or the second field plate portion (40).

6. The lateral isolated gate bipolar transistor device of claim 5 having a drift region length of 10-80 μm, wherein the collector/anode (30) is spaced by 5-18 μm away from the end (27) of the drift region (26).

7. The lateral isolated gate bipolar transistor device of claim 1, wherein a high-doped zone (52) is provided below the top of the silicon layer (24) between the field plate portion (40) adjacent to the collector/anode and the collector/anode (30) to provide a Gummel number sufficient to suppress a parasitic bipolar effect at the collector/anode of the LIGBT.

8. The lateral isolated gate bipolar transistor device of claim 7, wherein the high-doped zone (52) has a doping two or more times as high as the doping in the surrounding silicon layer (24).

9. The lateral isolated gate bipolar transistor device of claim 7, wherein the high-doped zone (52) ends short of the collector/anode (30).

10. The lateral isolated gate bipolar transistor device of claim 7, wherein the high-doped zone (52) ends at the field oxide layer (42).

11. The lateral isolated gate bipolar transistor device of claim 1, comprising a collector/anode contact out of metal, wherein the collector/anode contact extends over the collector/anode and drift region junction to prevent depletion in this region.

12. The lateral isolated gate bipolar transistor device of claim 11, wherein the collector/anode contact extends at least 2 μm over the collector/anode and drift region junction.

13. The lateral isolated gate bipolar transistor device of claim 1, wherein the dielectric layer comprises a thermally grown field oxide and drift oxide in between the emitter/cathode (28) and the collector/anode (30).

14. The lateral isolated gate bipolar transistor device of claim 1, wherein the gate electrode is extended by at least one metal field plate which are isolated by a dielectric and extends across the field oxide and drift oxide layer to almost an end thereof adjacent to the collector/anode.

15. The lateral isolated gate bipolar transistor device of claim 2, wherein the gate electrode is extended by at least one metal field plate which are isolated by a dielectric and extends across the field oxide and drift oxide layer to almost an end thereof adjacent to the collector/anode.

16. The lateral isolated gate bipolar transistor device of claim 3, wherein the gate electrode is extended by at least one metal field plate which are isolated by a dielectric and extends across the field oxide and drift oxide layer to almost an end thereof adjacent to the collector/anode.

17. The lateral isolated gate bipolar transistor device of claim 7, wherein the gate electrode is extended by at least one metal field plate which are isolated by a dielectric and extends across the field oxide and drift oxide layer to almost an end thereof adjacent to the collector/anode.

18. The lateral isolated gate bipolar transistor device of claim 11, wherein the gate electrode is extended by at least one metal field plate which are isolated by a dielectric and extends across the field oxide and drift oxide layer to almost an end thereof adjacent to the collector/anode.
